(19) United States
(12) Patent Application Publication
(10) Pub. No.: US 2023/0178598 A1
(43) Pub. Date: Jun. 8, 2023

(54) SELECTIVE DIPOLE LAYER MODULATION USING TWO-STEP INNER SPACER

(71) Applicant: INTERNATIONAL BUSINESS MACHINES CORPORATION, Armonk, NY (US)

(72) Inventors: Takashi Ando, Eastchester, NY (US); Ruilong Xie, Niskayuna, NY (US); Alexander Reznicek, Troy, NY (US); Pouya Hashemi, Purchase, NY (US)

(21) Appl. No.: 17/542,662

(22) Filed: Dec. 6, 2021

(51) Int. Cl. H01L 29/06; H01L 29/66; H01L 29/786; H01L 29/423; H01L 21/8234

(52) U.S. Cl. CPC H01L 29/0665; H01L 29/66553; H01L 29/78618; H01L 29/78696; H01L 29/42392; H01L 21/823412; H01L 21/823418

(57) ABSTRACT

A method is presented for selective dipole layer modulation. The method includes forming a nanosheet stack over a substrate, the nanosheet stack including alternating layers of a first semiconductor material, a second semiconductor material, and a third semiconductor material, etching the first and second semiconductor materials to define indentations, forming first inner spacers within the indentations, removing residual of the first semiconductor material, forming second inner spacers adjacent the first inner spacers, removing the remaining first and second semiconductor materials to define openings adjacent the first inner spacers, and filling the openings with a dipole layer stack to create multiple work function gate stacks with multiple threshold voltages (Vt) without metal gate patterning due to pinch-off exhibited between the first inner spacers and a nanosheet channel.

### BACKGROUND

The present invention relates generally to semiconductor devices, and more specifically, to selective dipole layer modulation by using a two-step inner spacer for multi-work function nanosheet metal oxide semiconductor field effect transistors (MOSFETs).

In nanometer scale devices, gate structures are often disposed between fin structures or other conducting structures, such as nanosheets. In many instances, the conducting or semiconducting structures are formed closer together due to scaling to smaller node technology sizes. This can be a limiting factor in the reduction of device size scaling. While fin field effect transistors (finFETs) and/or nanosheets can benefit from tight device-device spacing, these dimensions can limit device scaling. Further, devices needing a thicker dielectric for higher voltage operation are even more limited in the allowable dimensions. Higher voltage devices for input and/or output circuits need thicker gate dielectrics as compared to standard gate devices, which have a lower voltage and can be employed, e.g., in logic devices.

### SUMMARY

In accordance with an embodiment, a method is provided for selective dipole layer modulation. The method includes forming a nanosheet stack over a substrate, the nanosheet stack including alternating layers of a first semiconductor material, a second semiconductor material, and a third semiconductor material, etching the first and second semiconductor materials to define indentations, forming first inner spacers within the indentations, removing residual of the first semiconductor material, forming second inner spacers adjacent the first inner spacers, removing the remaining first and second semiconductor materials to define openings adjacent the first inner spacers, and filling the openings with a dipole layer stack to create multiple work function gate stacks with multiple threshold voltages (Vt) without metal gate patterning due to pinch-off exhibited between the first inner spacers and a nanosheet channel.

In accordance with another embodiment, a method is provided for selective dipole layer modulation. The method includes forming a plurality of nanosheet channels in a gate region of a transistor, forming an outer spacer between the nanosheet channels and in direct contact with a source/drain region, forming an inner spacer in direct contact with the outer spacer, wherein the inner spacer is positioned between the nanosheet channels, and depositing gate metal layers in the gate region, wherein only one of the gate metal layers is between the inner spacer and the nanosheet channel.

In accordance with yet another embodiment, a semiconductor device is provided. The semiconductor device includes a plurality of nanosheet channels disposed in a gate region of a transistor, an outer spacer disposed between the nanosheet channels and in direct contact with a source/drain region, an inner spacer disposed in direct contact with the outer spacer, wherein the inner spacer is positioned between the nanosheet channels, and gate metal layers disposed in the gate region, wherein only one of the gate metal layers is between the inner spacer and the nanosheet channel.

It should be noted that the exemplary embodiments are described with reference to different subject-matters. In particular, some embodiments are described with reference to method type claims whereas other embodiments have been described with reference to apparatus type claims. However, a person skilled in the art will gather from the above and the following description that, unless otherwise notified, in addition to any combination of features belonging to one type of subject-matter, also any combination between features relating to different subject-matters, in particular, between features of the method type claims, and features of the apparatus type claims, is considered as to be described within this document.

These and other features and advantages will become apparent from the following detailed description of illustrative embodiments thereof, which is to be read in connection with the accompanying drawings.

### BRIEF DESCRIPTION OF THE DRAWINGS

The invention will provide details in the following description of preferred embodiments with reference to the following figures wherein:

FIG. 1 is a cross-sectional view of a nanosheet stack formed over a substrate, in accordance with an embodiment of the present invention;

FIG. 2 is a cross-sectional view of the semiconductor structure of FIG. 1 where indentation of the sacrificial layers of the nanosheet stack is performed, in accordance with an embodiment of the present invention;

FIG. 3 is a cross-sectional view of the semiconductor structure of FIG. 2 where first inner spacers are formed adjacent the indented sacrificial layers, in accordance with an embodiment of the present invention;

FIG. 4 is a cross-sectional view of the semiconductor structure of FIG. 3 where the sacrificial layers are further etched, in accordance with an embodiment of the present invention;

FIG. 5 is a cross-sectional view of the semiconductor structure of FIG. 4 where second inner spacers are formed adjacent the first inner spacers, in accordance with an embodiment of the present invention;

FIG. 6 is a cross-sectional view of the semiconductor structure of FIG. 5 where source/drain regions are grown, an inter-layer dielectric (ILD) is deposited and planarized, in accordance with an embodiment of the present invention;

FIG. 7 is a cross-sectional view of the semiconductor structure of FIG. 6 where the dummy gate and the remaining sacrificial layer portions are selectively removed, in accordance with an embodiment of the present invention;

FIG. 8 is a cross-sectional view of the semiconductor structure of FIG. 7 where patterning is performed to remove the first inner spacer from the low-Vt device and where an organic planarization layer (OPL) is deposited in the high-Vt device, in accordance with an embodiment of the present invention;

FIG. 9 is a cross-sectional view of the semiconductor structure of FIG. 8 where the OPL is removed from the high-Vt device to expose the first inner spacers, in accordance with an embodiment of the present invention;

FIG. 10 is a cross-sectional view of the semiconductor structure of FIG. 9 where a high-k material and a dipole layer stack are deposited, and then amorphous silicon (a-Si) deposition and anneal are performed, in accordance with an embodiment of the present invention; and

FIG. 11 is a cross-sectional view of the semiconductor structure of FIG. 10 where the a-Si is removed, and a work function metal (WFM) and a conductive material are deposited, in accordance with an embodiment of the present invention.

Throughout the drawings, same or similar reference numerals represent the same or similar elements.

### DETAILED DESCRIPTION

Embodiments in accordance with the present invention provide methods and devices for selective dipole layer modulation by using a two-step inner spacer for multi-work function nanosheet metal oxide semiconductor field effect transistors (MOSFETs). Nanosheets provide for viable device architectures for scaling complementary metal oxide semiconductors (CMOS) beyond the 7 nm node. Thin gate dielectric nanosheet transistors can be used, e.g., for logic and static random access memory (SRAM) applications, whereas thick gate dielectric nanosheet transistors can be used, e.g., for high voltage applications.

Multiple work function gate stacks are beneficial to achieve complementary metal oxide semiconductor (CMOS) technology with multiple threshold voltages (Vt) on fully depleted channel architectures (e.g., FinFET, Nano sheet, etc.) to take advantage of higher mobility and smaller device variability due to the absence of channel doping. Conventional multiple work function schemes require patterning steps post high-k deposition to pattern a work function setting metal or dipole formation elements (e.g., La, Al). For nanosheet devices, it is challenging to perform such patterning steps post high-k deposition considering limited space between sheets, resulting in organic planarization layer (OPL) pinch off in small gaps, which is difficult to remove. Thus, there are no effective methods and/or structures to achieve multiple work function for nanosheet devices.

Embodiments in accordance with the present invention alleviate such issues by providing methods and devices where a first spacer is selectively formed on high Vt devices. Multi-Vt devices are formed without metal gate patterning due to pinch-off of the bottom TiN film between the first inner spacer and the channel. The NFET dipole layer stack includes TiN/oxide of Group IIA or IIIB element/TiN and the PFET dipole layer stack includes TiN/Al₂O₃ or TiO₂/TiN. Thus, the dipole element is absent near the channel edges for the high-Vt devices only. Multi-Vt is achieved by modulating the Vt only under the first inner spacer and keeping the middle channel portion the same, thus no need for metal patterning. As a result, the exemplary embodiments of the present invention enable multi-WF NFET and PFET without additional metal patterning after high-k deposition.

Examples of semiconductor materials that can be used in forming such structures include silicon (Si), germanium (Ge), silicon germanium alloys (SiGe), silicon carbide (SiC), silicon germanium carbide (SiGeC), III-V compound semiconductors and/or II-VI compound semiconductors. III-V compound semiconductors are materials that include at least one element from Group III of the Periodic Table of Elements and at least one element from Group V of the Periodic Table of Elements. II-VI compound semiconductors are materials that include at least one element from Group II of the Periodic Table of Elements and at least one element from Group VI of the Periodic Table of Elements.

It is to be understood that the present invention will be described in terms of a given illustrative architecture; however, other architectures, structures, substrate materials and process features and steps/blocks can be varied within the scope of the present invention. It should be noted that certain features cannot be shown in all figures for the sake of clarity. This is not intended to be interpreted as a limitation of any particular embodiment, or illustration, or scope of the claims.

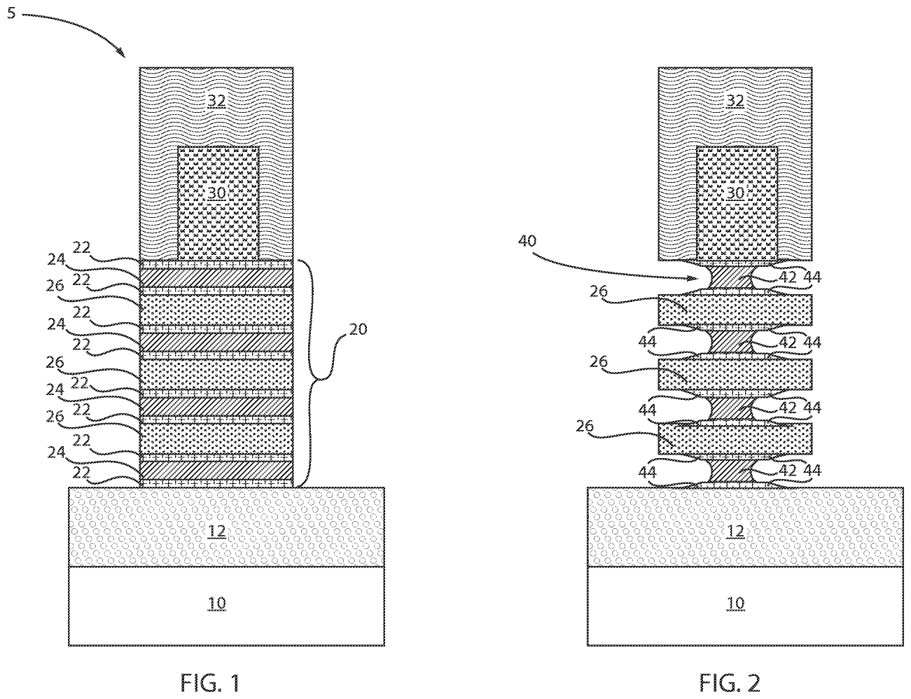

FIG. 1 is a cross-sectional view of a nanosheet stack formed over a substrate, in accordance with an embodiment of the present invention.

In various example embodiments, a semiconductor structure 5 includes a semiconductor substrate 10. A dielectric layer 12 is formed over the semiconductor substrate 10. A nanosheet stack 20 is formed over the dielectric layer 12. The nanosheet stack 20 can include, e.g., alternating layers of a first semiconductor material 22, a second semiconductor material 24, and a third semiconductor material 26. The first semiconductor material 22 can be, e.g., silicon germanium (SiGe), the second semiconductor material 24 can be, e.g., SiGe, and the third semiconductor material 26 can be, e.g., silicon (Si). In one example, the Ge content of the first semiconductor material 22 can be about 25%. One skilled in the art can contemplate a higher or lower concentration of Ge. In one example, the Ge content of the second semiconductor material 24 can be about 35%. One skilled in the art can contemplate a higher or lower concentration of Ge.

A dummy gate 30 can be formed over the nanosheet stack 20. A hardmask 32 can be formed over the dummy gate 30.

In one or more embodiments, the substrate 10 can be a semiconductor or an insulator with an active surface semiconductor layer. The substrate 10 can be crystalline, semi-crystalline, microcrystalline, or amorphous. The substrate 10 can be essentially (e.g., except for contaminants) a single element (e.g., silicon), primarily (e.g., with doping) of a single element, for example, silicon (Si) or germanium (Ge), or the substrate 10 can include a compound, for example, Al₂O₃, SiO₂, GaAs, SiC, or SiGe. The substrate 10 can also have multiple material layers, for example, a semiconductor-on-insulator substrate (SeOI), a silicon-on-insulator substrate (SOI), germanium-on-insulator substrate (GeOI), or silicon-germanium-on-insulator substrate (SGOI). The substrate 10 can also have other layers forming the substrate 10, including high-k oxides and/or nitrides. In one or more embodiments, the substrate 10 can be a silicon wafer. In an embodiment, the substrate 10 is a single crystal silicon wafer.

The dielectric layer 12 can include, but is not limited to, SiN, SiOCN, SiOC, SiBCN, SO2, or ultra-low-k (ULK) materials, such as, for example, porous silicates, carbon doped oxides, silicon dioxides, silicon nitrides, silicon oxynitrides, carbon-doped silicon oxide (SiCOH) and porous variants thereof, silsesquioxanes, siloxanes, or other dielectric materials having, for example, a dielectric constant in the range of about 2 to about 10.

In some embodiments, the dielectric layer 12 can be conformally deposited using atomic layer deposition (ALD) or, chemical vapor deposition (CVD). Variations of CVD processes suitable for forming the dielectric layer 12 include, but are not limited to, Atmospheric Pressure CVD (APCVD), Low Pressure CVD (LPCVD) and Plasma Enhanced CVD (PECVD), Metal-Organic CVD (MOCVD) and combinations thereof can also be employed.

Referring to, e.g., the nanosheet stack 20, although it is specifically contemplated that the first and second semiconductor materials 22/24 can be formed from silicon germanium and that the third semiconductor materials 26 can be formed from silicon, it should be understood that any appropriate materials can be used instead, as long as the two semiconductor materials have etch selectivity with respect to one another. As used herein, the term “selective” in reference to a material removal process denotes that the rate of material removal for a first material is greater than the rate of removal for at least another material of the structure to which the material removal process is being applied. The alternating semiconductor materials 22/24/26 can be deposited by any appropriate mechanism. It is specifically contemplated that the semiconductor materials 22/24/26 can be epitaxially grown from one another, but alternate deposition processes, such as chemical vapor deposition (CVD), physical vapor deposition (PVD), atomic layer deposition (ALD), or gas cluster ion beam (GCIB) deposition, are also contemplated.

Dummy gate 30 materials include, but are not limited to, a thin layer of dummy oxide SiO₂ followed by any one or more of amorphous or polycrystalline Si, SiO₂, SiON, SiGe, Ge, GeO₂, amorphous C, BC, CN, etc.

The hardmask 32 materials can include any of one or more of SiN, SiCN, SiBN and/or SiBCN, among other materials. The hardmask 32 can be an oxide, for example, a silicon oxide hardmask. The hardmask 32 can be patterned by any suitable patterning techniques, including but not limited to, lithography followed by etching, sidewall image transfer (SIT), self-aligned double patterning (SADP), self-aligned multiple patterning (SAMP), self-aligned quadruple patterning (SAQP), or any suitable combination of those techniques.

FIG. 2 is a cross-sectional view of the semiconductor structure of FIG. 1 where indentation of the sacrificial layers of the nanosheet stack is performed, in accordance with an embodiment of the present invention.

In various example embodiments, the first semiconductor material layers 22 and the second semiconductor material layers 24 are etched to create indentations 40. The etching results in semiconductor material layer portions 42 (35% Ge content SiGe) formed between semiconductor material layer portions 44 (25% Ge content SiGe). The semiconductor material layer portions 44 include residual areas extending beyond the edges of the semiconductor material layer portions 42. Thus, the semiconductor material layer portions 42 (35% Ge content SiGe) etch deeper than the semiconductor material layer portions 44 (25% Ge content SiGe).

The etching can include a dry etching process such as, for example, reactive ion etching, plasma etching, ion etching or laser ablation. The etching can further include a wet chemical etching process in which one or more chemical etchants are used to remove portions of the blanket layers that are not protected by the patterned photoresist.

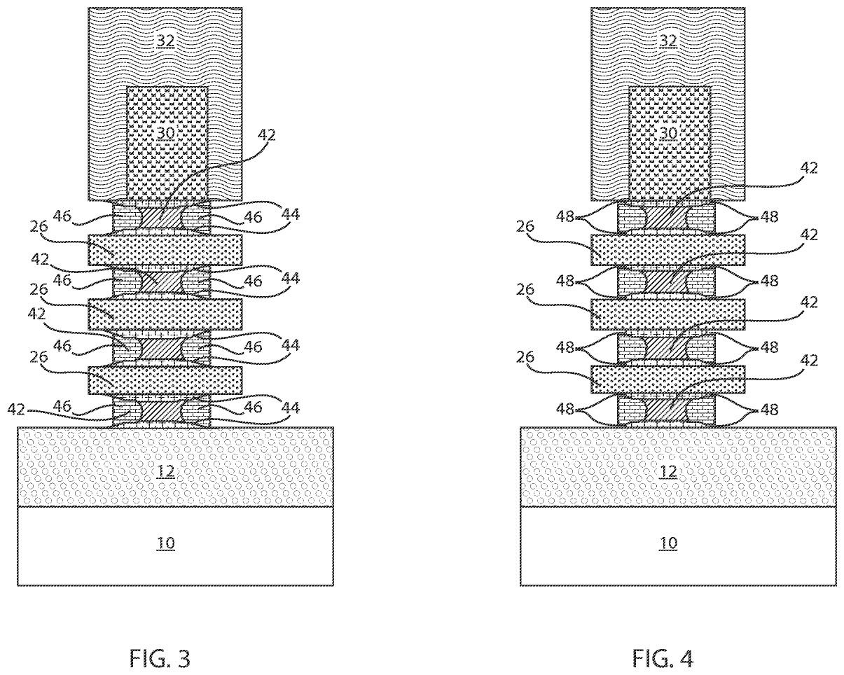

FIG. 3 is a cross-sectional view of the semiconductor structure of FIG. 2 where first inner spacers are formed adjacent the indented sacrificial layers, in accordance with an embodiment of the present invention.

In various example embodiments, first inner spacers 46 are formed adjacent or on opposed ends of the semiconductor material layer portions 42 (35% Ge content SiGe). The first inner spacers 46 directly contact the residual areas of the semiconductor material layer portions 44 (25% Ge content SiGe).

The first inner spacers 46 can include any of one or more of SiN, SiBN, SiCN and/or SiBCN films. In one example, the first inner spacers 46 are SiC.

FIG. 4 is a cross-sectional view of the semiconductor structure of FIG. 3 where the sacrificial layers are further etched, in accordance with an embodiment of the present invention.

In various example embodiments, the residual areas of the semiconductor material layer portions 44 (25% Ge content SiGe) are completely removed to create openings or voids 48 at the top and bottom edges of the first inner spacers 46. The complete removal of residual areas of the semiconductor material layer portions 44 (25% Ge content SiGe) ensures no S/D damage during SiGe channel release.

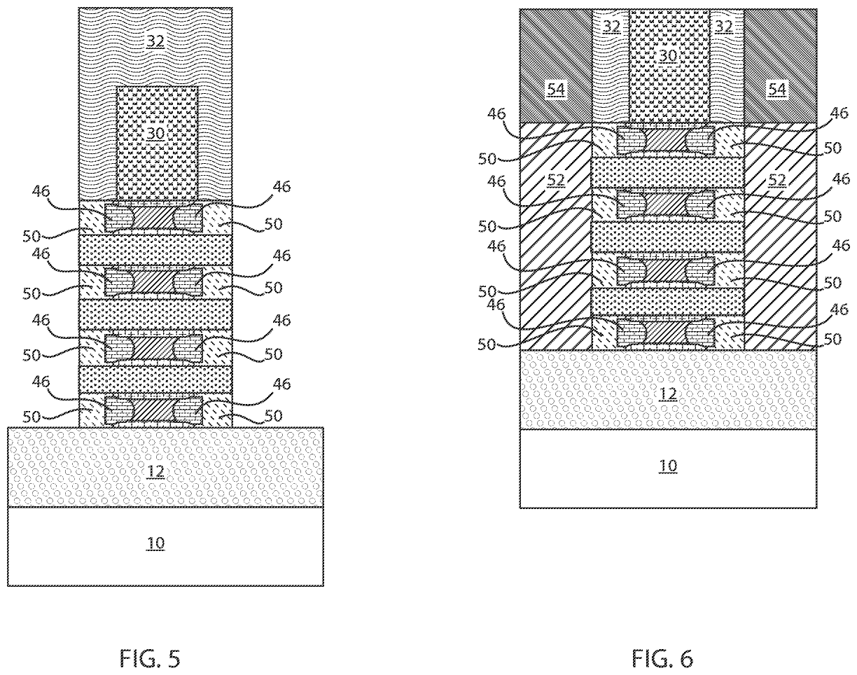

FIG. 5 is a cross-sectional view of the semiconductor structure of FIG. 4 where second inner spacers are formed adjacent the first inner spacers, in accordance with an embodiment of the present invention.

In various example embodiments, second inner spacers 50 are formed adjacent the first inner spacers 46. The second inner spacers 50 directly contact the first inner spacers 46. The second inner spacers 50 directly contact the top and bottom edges of the first inner spacers 46, and sidewalls of the remaining semiconductor material layer portions 44 (25% Ge content SiGe).

The second inner spacers 50 can include any of one or more of SiN, SiBN, SiCN and/or SiBCN films.

FIG. 6 is a cross-sectional view of the semiconductor structure of FIG. 5 where source/drain regions are grown, an inter-layer dielectric (ILD) is deposited and planarized, in accordance with an embodiment of the present invention.

In various example embodiments, source/drain regions 52 are grown, an inter-layer dielectric (ILD) 54 is deposited over the source/drain regions 52, and is planarized by, e.g., chemical mechanical polishing (CMP). The source/drain regions 52 directly contact sidewalls of the second inner spacers 50. The source/drain regions 52 directly contact sidewalls of the third semiconductor material 26.

The terms “epitaxial growth” and “epitaxial deposition” refer to the growth of a semiconductor material on a deposition surface of a semiconductor material, in which the semiconductor material being grown has substantially the same crystalline characteristics as the semiconductor material of the deposition surface. The term “epitaxial material” denotes a material that is formed using epitaxial growth. In some embodiments, when the chemical reactants are controlled and the system parameters set correctly, the depositing atoms arrive at the deposition surface with sufficient energy to move around on the surface and orient themselves to the crystal arrangement of the atoms of the deposition surface. Thus, in some examples, an epitaxial film deposited on a {100} crystal surface will take on a {100} orientation.

The ILD 54 can be any suitable dielectric such as, for example, silicon oxide (SiO), silicon nitride (SiN), silicon oxynitride, silicon boron carbon nitride (SiBCN), silicon oxygen carbon nitride (SiOCN), silicon oxygen carbon (SiOC), silicon carbon nitride (SiCN), hydrogenated oxidized silicon carbon (SiCOH), or any suitable combination of those materials. In one example, the ILD 54 can be a low-k oxide.

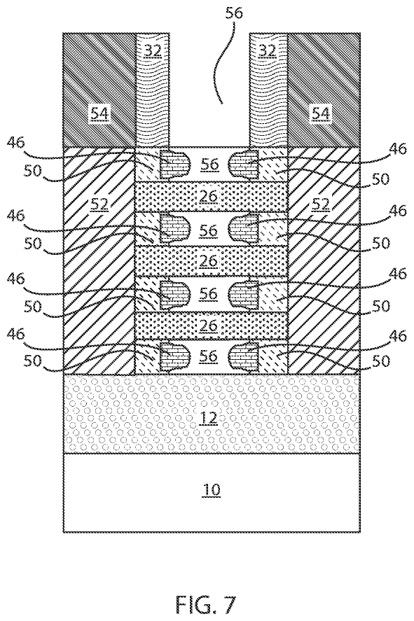

FIG. 7 is a cross-sectional view of the semiconductor structure of FIG. 6 where the dummy gate and the remaining sacrificial layer portions are selectively removed, in accordance with an embodiment of the present invention.

In various example embodiments, the dummy gate 30 and the remaining sacrificial material layer portions 22/24 are selectively removed resulting in gaps or voids or openings 56. The gaps 56 are formed between the first inner spacers 46.

The dummy gate 30 can be removed by implementing an RIE process and/or a wet etching process. If the dummy gate 30 is made of amorphous or poly-Si, it can be etched in hot NH₄OH or Tetramethylammonium hydroxide (TMAH) chemistries in a manner that is selective to the ILD 54 and the hardmask 32.

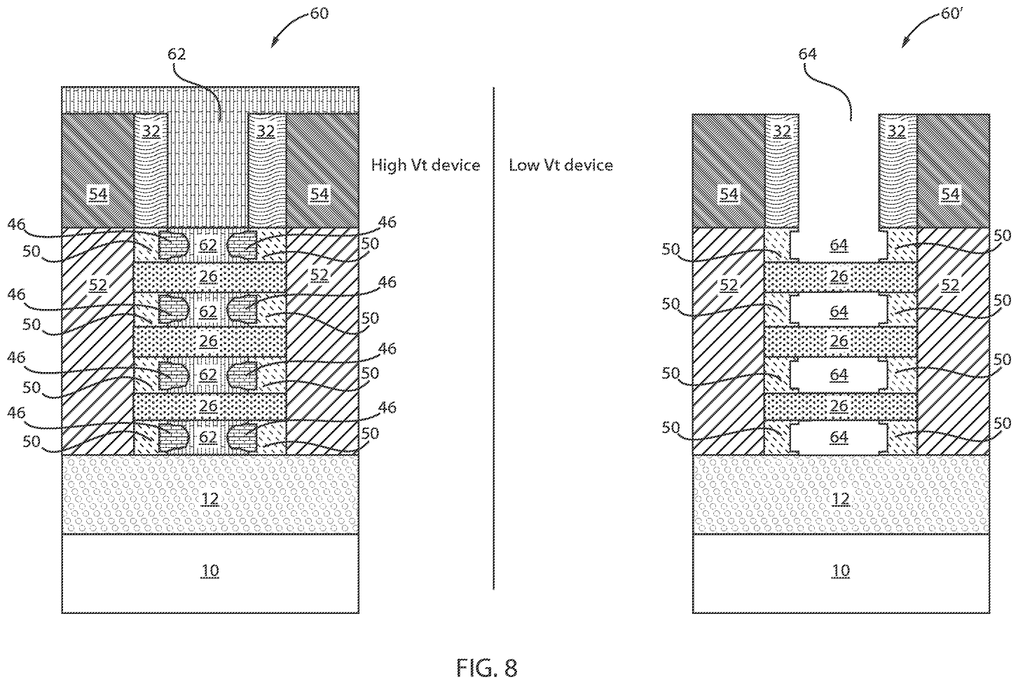

FIG. 8 is a cross-sectional view of the semiconductor structure of FIG. 7 where patterning is performed to remove the first inner spacer from the low-Vt device and where an organic planarization layer (OPL) is deposited in the high-Vt device, in accordance with an embodiment of the present invention.

In various example embodiments, for a low-Vt device 60′, the first inner spacers 46 are selectively removed to create openings or gaps 64. The size of the gaps 64 are defined by the third semiconductor material 26 and the second inner spacers 50.

In various example embodiments, for a high-Vt device 60, an OPL 62 is deposited within the gaps 56. The OPL 62 directly contacts the first inner spacers 46, as well as top an bottom edges of the second inner spacers 50.

The OPL 62 can be formed at a predetermined thickness to provide reflectivity and topography control during etching of the layers below. The OPL 62 can include an organic material, such as a polymer.

Regarding FIGS. 7 and 8, the dry and wet etching processes can have etching parameters that can be tuned, such as etchants used, etching temperature, etching solution concentration, etching pressure, source power, RF bias voltage, RF bias power, etchant flow rate, and other suitable parameters. Dry etching processes can include a biased plasma etching process that uses a chlorine-based chemistry. Other dry etchant gasses can include Tetrafluoromethane (CF₄), nitrogen trifluoride (NF₃), sulfur hexafluoride (SF₆), and helium (He), and Chlorine trifluoride (ClF₃). Dry etching can also be performed anisotropically using such mechanisms as DRIE (deep reactive-ion etching). Chemical vapor etching can be used as a selective etching method, and the etching gas can include hydrogen chloride (HCl), Tetrafluoromethane (CF₄), and gas mixture with hydrogen (H₂). Chemical vapor etching can be performed by CVD with suitable pressure and temperature.

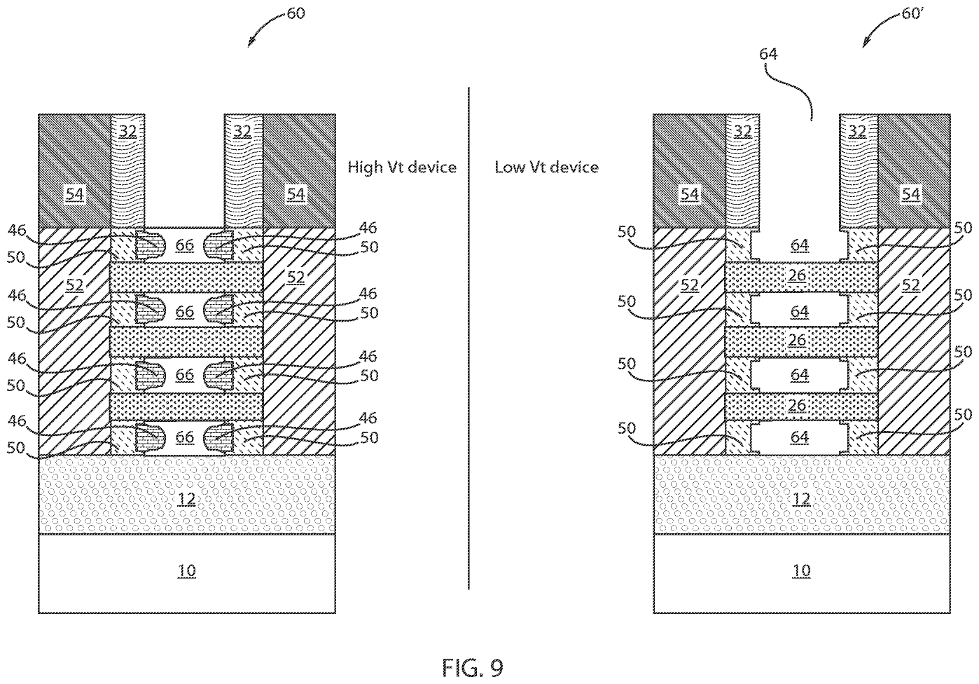

FIG. 9 is a cross-sectional view of the semiconductor structure of FIG. 8 where the OPL is removed from the high-Vt device to expose the first inner spacers, in accordance with an embodiment of the present invention.

In various example embodiments, in the high-Vt device 60, the OPL 62 is removed to expose the first inner spacers 46. In one example, the OPL 62 can be removed by ashing. The removal of the OPL 62 results in openings 66 between the first inner spacers 46.

The low-Vt device 60′ remains intact.

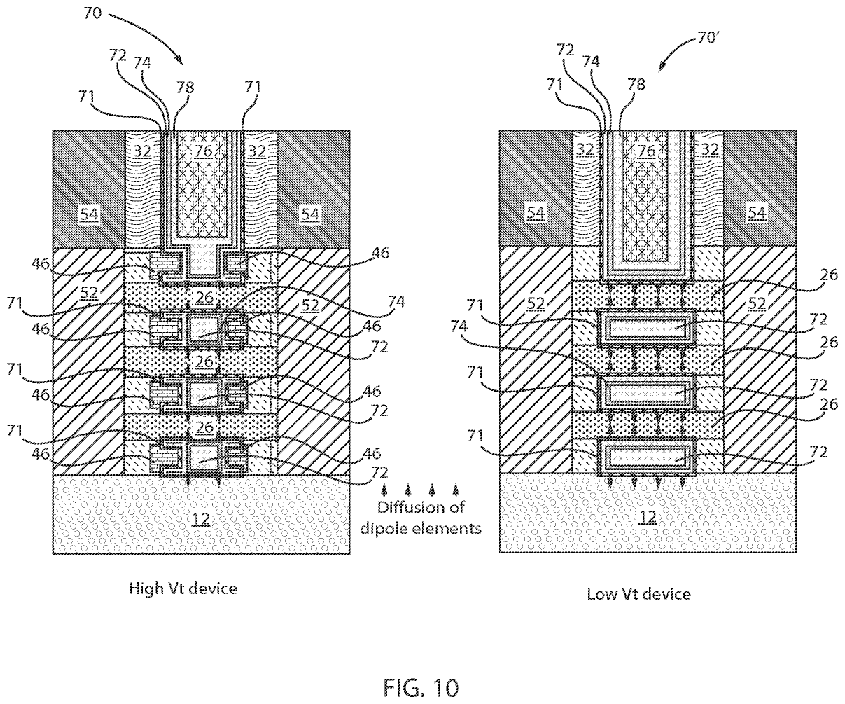

FIG. 10 is a cross-sectional view of the semiconductor structure of FIG. 9 where a high-k material and a dipole layer stack are deposited, and then amorphous silicon (a-Si) deposition and anneal are performed, in accordance with an embodiment of the present invention.

In various example embodiments, a dipole layer stack is deposited including a first metal film 72, dipole element 74, and a second metal film 78, and then an amorphous silicon (a-Si) 76 deposition and anneal take place. The first metal film 72 can be, e.g., TiN, and the second metal film 78 can also be, e.g., TiN. The dipole layer stack is deposited over a high-k layer 71.

The dipole elements 74 can be, e.g., La, Al, etc.

For an NFET device, the dipole layer stack includes TiN/oxide of Group IIA or IIIB element/TiN.

For a PFET device, the dipole layer stack includes TiN/Al₂O₃ or TiO₂/TiN.

The first or second TiN layer 78 can have a thickness that is set to pinch off the space between the nanosheet channel and the first inner spacers 46. The dipole elements 74 are diffused through the bottom TiN layer after the drive-in anneal.

In the high-Vt device 70, dipole elements 74 are absent in the high-k material 72 near the channel edges. The first metal film 72 fills the space between the first inner spacers 46 and the third semiconductor material 26. The diffusion of the dipole elements 74 is shown by the arrows that point toward the third semiconductor material 26.

In the low-Vt device 70′, dipole elements 74 are present near the channel edges. The diffusion of the dipole elements 74 is shown by the arrows that point toward the third semiconductor material 26.

In various embodiments, the high-k materials of high-k layer 71 can include but are not limited to work function metals such as titanium nitride, titanium carbide, titanium aluminum carbide, tantalum nitride and tantalum carbide; conducting metals such as tungsten, aluminum and copper; and oxides such as silicon dioxide (SiO₂), hafnium oxide (e.g., HfO₂), hafnium silicon oxide (e.g., HfSiO₄), hafnium silicon oxynitride (Hf_{w}SiₓO_{y}N_{z}), lanthanum oxide (e.g., La₂O₃), lanthanum aluminum oxide (e.g., LaAlO₃), zirconium oxide (e.g., ZrO₂), zirconium silicon oxide (e.g., ZrSiO₄), zirconium silicon oxynitride (Zr_{w}SiₓO_{y}N_{z}), tantalum oxide (e.g., TaO₂, Ta₂O₅), titanium oxide (e.g., TiO₂), barium strontium titanium oxide (e.g., BaTiO₃—SrTiO₃), barium titanium oxide (e.g., BaTiO₃), strontium titanium oxide (e.g., SrTiO₃), yttrium oxide (e.g., Y₂O₃), aluminum oxide (e.g., Al₂O₃), lead scandium tantalum oxide (Pb(ScₓTa₁₋ₓ)O₃), and lead zinc niobate (e.g., PbZn_{1/3}Nb_{2/3} O₃).

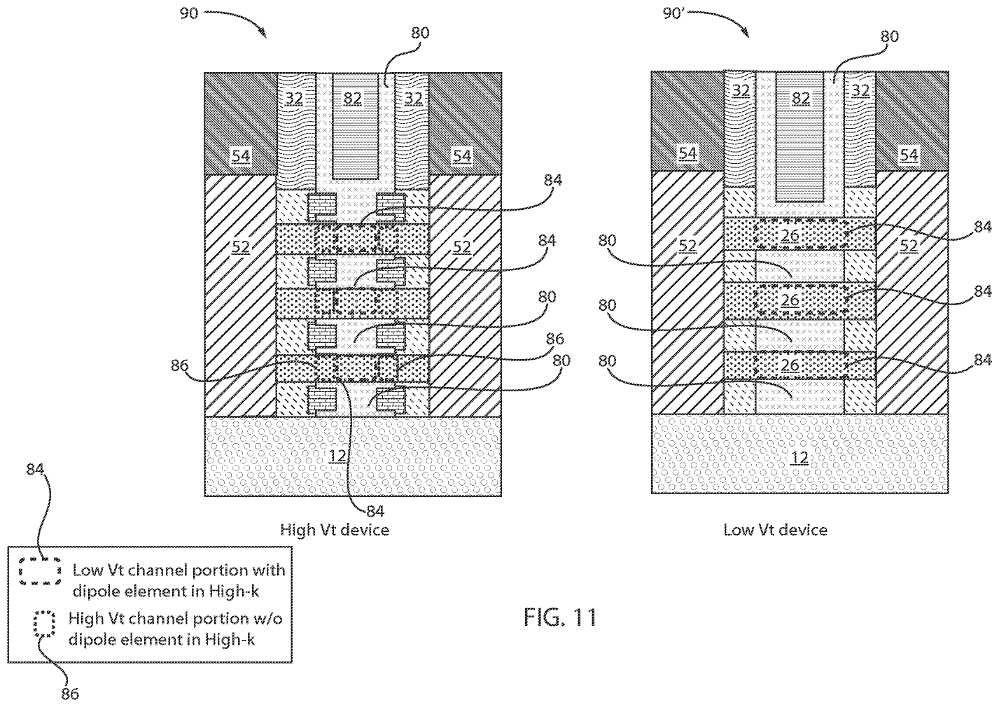

FIG. 11 is a cross-sectional view of the semiconductor structure of FIG. 10 where the a-Si is removed, and a work function metal (WFM) and a conductive material are deposited, in accordance with an embodiment of the present invention.

In various example embodiments, the a-Si 76 is removed, and a work function metal (WFM) 80 and a conductive material 82 are deposited. The WFM 80 and the conductive material 82 can be planarized by, e.g., CMP.

In the high-Vt device 90, the low-Vt channel portions 84 are formed between high-Vt channel portions 86. The low-Vt channel portions 84 and the high-Vt channel portions 86 are horizontally aligned with the third semiconductor material 26 (e.g., Si layer). The low-Vt channel portions 84 and the high-Vt channel portions 86 are horizontally offset from the first and second inner spacers 46, 50. The high-Vt channel portions 86 are vertically aligned with the WFM 80. The low-Vt channel portions 84 are vertically aligned with the first inner spacers 46.

In the low-Vt device 90′, only low-Vt channel portions 84 are formed. The-Vt channel portions 84 are horizontally aligned with the third semiconductor material 26 (e.g., Si layer). The low-Vt channel portions 84 are vertically offset from the second inner spacers 50.

The WFM 80 can be a metal, such as, e.g., copper (Cu), cobalt (Co), aluminum (Al), platinum (Pt), gold (Au), tungsten (W), titanium (Ti), or any combination and nitrides thereof. The metal can be deposited by a suitable deposition process, for example, chemical vapor deposition (CVD), plasma enhanced chemical vapor deposition (PECVD), physical vapor deposition (PVD), plating, thermal or e-beam evaporation, or sputtering. In various exemplary embodiments, the height of the WFM 80 can be reduced by chemical-mechanical polishing (CMP) and/or etching. Therefore, the planarization process can be provided by CMP. Other planarization process can include grinding and polishing.

The conductive material 82, can be, e.g., tungsten (W).

Non-limiting examples of suitable conductive materials include doped polycrystalline or amorphous silicon, germanium, silicon germanium, a metal (e.g., tungsten, titanium, tantalum, ruthenium, zirconium, cobalt, copper, aluminum, lead, platinum, tin, silver, gold), a conducting metallic compound material (e.g., tantalum nitride, titanium nitride, tantalum carbide, titanium carbide, titanium aluminum carbide, tungsten silicide, tungsten nitride, ruthenium oxide, cobalt silicide, nickel silicide), carbon nanotube, conductive carbon, graphene, or any suitable combination of these materials. The conductive material can further include dopants that are incorporated during or after deposition. The conductive metal can be deposited by a suitable deposition process, for example, CVD, PECVD, PVD, plating, thermal or e-beam evaporation, and sputtering.

In summary, the exemplary embodiments of the present invention include methods and devices for selective dipole layer modulation by using a two-step inner spacer for multi-work function nanosheet metal oxide semiconductor field effect transistors (MOSFETs). The exemplary embodiments can be used for multi-Vt by modifying the work function only near the edges of nanosheet FETs to avoid patterning films within the limited space between sheets. The two inner spacers enable multiple work function devices without post metal patterning, which facilitates scaling of stacked nanosheet devices. Moreover, the two inner spacers enable multiple work function devices with uniform sheet-to-sheet spacing without changing the high-k process. Stated differently, the exemplary embodiments enable a metal patterning free multiple work function for stacked nanosheets with uniform high-k dielectrics.

As a result, the semiconductor structure of the exemplary embodiments includes a plurality of nanosheet channels in a gate region of a transistor, an outer spacer located between each of the nano sheet channels and in contact with a source/drain region, a pinch spacer in contact with the outer spacer of and between each of the nanosheet channels, and two or more gate metal layers in the gate region, where only one of the metals is between the pinch spacer and the nanosheet channel.

It is to be understood that the present invention will be described in terms of a given illustrative architecture; however, other architectures, structures, substrate materials and process features and steps/blocks can be varied within the scope of the present invention.

It will also be understood that when an element such as a layer, region or substrate is referred to as being “on” or “over” another element, it can be directly on the other element or intervening elements can also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements can be present. In contrast, when an element is referred to as being “directly connected” or “directly coupled” to another element, there are no intervening elements present.

The present embodiments can include a design for an integrated circuit chip, which can be created in a graphical computer programming language, and stored in a computer storage medium (such as a disk, tape, physical hard drive, or virtual hard drive such as in a storage access network). If the designer does not fabricate chips or the photolithographic masks used to fabricate chips, the designer can transmit the resulting design by physical mechanisms (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which include multiple copies of the chip design in question that are to be formed on a wafer. The photolithographic masks are utilized to define areas of the wafer (and/or the layers thereon) to be etched or otherwise processed.

Methods as described herein can be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher level carrier) or in a multichip package (such as a ceramic carrier that has either or both surface interconnections or buried interconnections). In any case, the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

It should also be understood that material compounds will be described in terms of listed elements, e.g., SiGe. These compounds include different proportions of the elements within the compound, e.g., SiGe includes SiₓGe₁₋ₓ where x is less than or equal to 1, etc. In addition, other elements can be included in the compound and still function in accordance with the present embodiments. The compounds with additional elements will be referred to herein as alloys. Reference in the specification to “one embodiment” or “an embodiment” of the present invention, as well as other variations thereof, means that a particular feature, structure, characteristic, and so forth described in connection with the embodiment is included in at least one embodiment of the present invention. Thus, the appearances of the phrase “in one embodiment” or “in an embodiment”, as well any other variations, appearing in various places throughout the specification are not necessarily all referring to the same embodiment.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This can be extended, as readily apparent by one of ordinary skill in this and related arts, for as many items listed.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

Spatially relative terms, such as “beneath,” “below,” “lower,” “above,” “upper,” and the like, can be used herein for ease of description to describe one element's or feature's relationship to another element(s) or feature(s) as illustrated in the FIGS. It will be understood that the spatially relative terms are intended to encompass different orientations of the device in use or operation in addition to the orientation depicted in the FIGS. For example, if the device in the FIGS. is turned over, elements described as “below” or “beneath” other elements or features would then be oriented “above” the other elements or features. Thus, the term “below” can encompass both an orientation of above and below. The device can be otherwise oriented (rotated 90 degrees or at other orientations), and the spatially relative descriptors used herein can be interpreted accordingly. In addition, it will also be understood that when a layer is referred to as being “between” two layers, it can be the only layer between the two layers, or one or more intervening layers can also be present.

It will be understood that, although the terms first, second, etc. can be used herein to describe various elements, these elements should not be limited by these terms. These terms are only used to distinguish one element from another element. Thus, a first element discussed below could be termed a second element without departing from the scope of the present concept.

Having described preferred embodiments of methods and devices for selective dipole layer modulation by using a two-step inner spacer for multi-work function nanosheet metal oxide semiconductor field effect transistors (MOSFETs) (which are intended to be illustrative and not limiting), it is noted that modifications and variations can be made by persons skilled in the art in light of the above teachings. It is therefore to be understood that changes may be made in the particular embodiments described which are within the scope of the invention as outlined by the appended claims. Having thus described aspects of the invention, with the details and particularity required by the patent laws, what is claimed and desired protected by Letters Patent is set forth in the appended claims.

1. A method for selective dipole layer modulation, the method comprising:
forming a nanosheet stack over a substrate, the nanosheet stack including alternating layers of a first semiconductor material, a second semiconductor material, and a third semiconductor material;
etching the first and second semiconductor materials to define indentations;
forming first inner spacers within the indentations;
removing residual of the first semiconductor material;
forming second inner spacers adjacent the first inner spacers;
removing the remaining first and second semiconductor materials to define openings adjacent the first inner spacers; and
filling the openings with a dipole layer stack to create multiple work function gate stacks with multiple threshold voltages (Vt) without metal gate patterning due to pinch-off exhibited between the first inner spacers and a nanosheet channel.

2. The method of claim 1, wherein the dipole layer stack includes a first TiN layer, dipole elements, and a second TiN layer.

3. The method of claim 2, wherein the dipole elements are diffused through the first TiN layer.

4. The method of claim 3, wherein the first TiN layer pinches off the space between the nanosheet channel and the first inner spacers.

5. The method of claim 4, wherein the dipole elements are absent near edges of the nanosheet channel when constructing a high-Vt device.

6. The method of claim 4, wherein the dipole elements are present near edges of the nanosheet channel when constructing a low-Vt device.

7. The method of claim 1, wherein the second inner spacers directly contact source/drain regions.

8. The method of claim 7, wherein the third semiconductor material is silicon (Si), the third semiconductor material directly contacting sidewalls of the source/drain regions.

9. A method for selective dipole layer modulation, the method comprising:
forming a plurality of nanosheet channels in a gate region of a transistor;
forming an outer spacer between the nanosheet channels and in direct contact with a source/drain region;
forming an inner spacer in direct contact with the outer spacer, wherein the inner spacer is positioned between the nanosheet channels; and
depositing gate metal layers in the gate region, wherein only one of the gate metal layers is between the inner spacer and the nanosheet channel.

10. The method of claim 9, wherein the gate metal layers include a first TiN layer, dipole elements, and a second TiN layer.

11. The method of claim 10, wherein the dipole elements are diffused through the first TiN layer.

12. The method of claim 11, wherein the first TiN layer pinches off the space between the nanosheet channel and the inner spacer.

13. The method of claim 12, wherein the dipole elements are absent near edges of the nanosheet channel when constructing a high-Vt device.

14. The method of claim 12, wherein the dipole elements are present near edges of the nanosheet channel when constructing a low-Vt device.

15. A semiconductor device comprising:
a plurality of nanosheet channels disposed in a gate region of a transistor;
an outer spacer disposed between the nanosheet channels and in direct contact with a source/drain region;
an inner spacer disposed in direct contact with the outer spacer, wherein the inner spacer is positioned between the nanosheet channels; and
gate metal layers disposed in the gate region, wherein only one of the gate metal layers is between the inner spacer and a nanosheet channel of the plurality of nanosheet channels.

16. The semiconductor device of claim 15, wherein the gate metal layers include a first TiN layer, dipole elements, and a second TiN layer.

17. The semiconductor device of claim 16, wherein the first TiN layer pinches off a space between the inner spacer and the nanosheet channel.

18. The semiconductor device of claim 16, wherein the dipole elements are absent near edges of the nanosheet channel.

19. The semiconductor device of claim 15, wherein the outer spacer directly contacts source/drain regions.

20. The semiconductor device of claim 15, wherein the inner spacer includes silicon carbide (SiC) and the outer spacer includes silicon nitride (SiN).
